(19) United States
(12) Patent Application Publication
(10) Pub. No.: US 2017/0169140 A1
(43) Pub. Date: Jun. 15, 2017

(54) SIMULATION TEST SYSTEM OF CLUSTER-BASED MICROGRID INTEGRATED WITH ENERGY STORAGE

(71) Applicant: NATIONAL CHUNG SHAN INSTITUTE OF SCIENCE AND TECHNOLOGY, Taoyuan City (TW)

(72) Inventors: CHIEN-HAO CHEN, TAOYUAN CITY (TW); YING-SUN HUANG, TAOYUAN CITY (TW); YU-JEN LIU, MINXIONG TOWNSHIP (TW); GARY W. CHANG, MINXIONG TOWNSHIP (TW); SHANG-YI CHEN, MINXIONG TOWNSHIP (TW)

(21) Appl. No.: 14/966,056

(22) Filed: Dec. 11, 2015

(51) Int. Cl. G06F 17/50; G01R 31/40

(52) U.S. Cl. CPC G06F 17/5009; G01R 31/40

(57) ABSTRACT

A simulation test system of a cluster-based microgrid integrated with energy storages is characterized in that an operation simulation test of a physical microgrid system is conducted with a computer as well as a power generation data and a power consumption data which are imported. Hence, the user can verify the feasibility of applying various design concepts and ideas, such as controller parameter design and system energy management strategies, to a physical microgrid system, without installing or using any physical apparatuses.

### FIELD OF TECHNOLOGY

The present invention relates to simulation test systems and more particularly to a simulation test system of a cluster-based microgrid integrated with energy storages.

### BACKGROUND

A power supply mode has been the major way of transmitting grid electrical power to clients by electric utility giants. In the face of the mounting demand for electrical power, the aforesaid centralized power management is disadvantageously inflexible because of high operation costs and system control management and thus unable to meet the increasingly strict requirements of power system operation safety and reliability which concerns the clients. Hence, microgrid system technology which enables multiple power management modes with regard to power generation, transmission and distribution was developed to achieve high energy utilization efficiency and thus enhance system reliability and grid safety on condition that the microgrid system operates efficiently, flexibly and independently.

In order to achieve the above objective of allowing a microgrid system to operate efficiently, flexibly and independently, the microgrid system must verify the feasibility of its system energy management strategies and controller design at the R&D state. To this end, the related prior art discloses constructing a physical microgrid system and then conducting an on-site system test to observe any responses given by the system during the physical test. However, conducting a test with a physical system is disadvantageously characterized in that, to adjust a design parameter anew and conduct the test again to verify the adjusted design parameter, plenty of physical apparatuses in the system must be adjusted accordingly in terms of their parameters and undergo wiring changes, not to mention that new apparatus components must be created or removed. As a result, the physical test is time-consuming and incurs high costs. Furthermore, the physical test predisposes test technicians to hazards arising from high-voltage power.

During the R&D stage, due to a lack of applicable physical tools, there are difficulties in applying plenty of forward-looking design concepts and ideas, such as controller-related control strategies and novel hardware frameworks, to the physical microgrid systems to effectuate physical construction and conduct related tests. As a result, the feasibility of the forward-looking design concepts and ideas cannot be evaluated by any test.

As mentioned before, physical system tests are time-consuming, incur high costs, predispose test technicians to hazards, and fail to verify the feasibility of the forward-looking design concepts and ideas. Hence, it is imperative to provide a test system that substitutes for a physical test.

### SUMMARY

It is an objective of the present invention to provide a test system which substitutes for a physical test, saves time, cuts test costs, and enhances safety.

Another objective of the present invention is to verify the feasibility of applying various design concepts and ideas, such as controller parameter design and system energy management strategies, to a physical microgrid system according to parameters configured by users.

In order to achieve the above and other objectives, the present invention provides a simulation test system of a microgrid, wherein an operation simulation test of a physical microgrid system is performed with a computer as well as a power generation data and a power consumption data which are imported, the computer comprising: a power generation module for simulating a physical power generation module of a physical microgrid system according to the power generation data and sending a DC power generation power data; a DC-AC inverter control module having a predetermined pulse width modulation parameter to provide a basis of adjustment and control of AC power; an AC end module comprising a DC-AC inverter unit and an AC utility grid unit, with the AC end module adapted to simulate a load of a physical microgrid system according to the power consumption data, wherein the DC-AC inverter unit connects with the DC-AC inverter control module and the power generation module to convert a portion attributed to the DC power generation power data and supplied to the load into a first power supply data according to the pulse width modulation parameter, wherein the AC utility grid unit provides a second power supply data selectively to the load; an energy storage module connected to the power generation module and the AC end module to simulate a physical energy storage module of a physical microgrid system, wherein the energy storage module comprises an energy storage unit and a bidirectional DC converter unit connected to the AC utility grid unit of the AC end module through the DC-AC inverter unit, wherein the energy storage unit connects with the DC-AC inverter unit to provide a third power supply data selectively according to the pulse width modulation parameter, wherein the bidirectional DC converter unit receives one of the second power supply data and the DC power generation power data to thereby provide a charging data to the energy storage module, wherein the DC power generation power data received by the energy storage module is a power data left over from the first power supply data consumed by the load; and a data display module connected to the power generation module, the DC-AC inverter control module, the AC end module and the energy storage module to enable parameter configuration of the power generation data, the power consumption data, the pulse width modulation parameter and the second power supply data, enable display of the DC power generation power data, the first power supply data and the third power supply data, and display a degree of equilibrium of a combination of a power data required for the load and the first through third power supply data.

Regarding the simulation test system, the power generation module is a solar power generation module comprising a daily irradiance parameter input unit which a user enters a daily irradiance parameter data and a maximum power tracking unit for tracking maximum power generation power and maintaining stability of DC voltage, wherein the power generation data includes the daily irradiance parameter data entered and an adjustment parameter for use in adjusting the daily irradiance parameter data with the maximum power tracking unit to thereby determine the DC power generation power data.

Regarding the simulation test system, the power generation data further comprises a solar power generation equipment parameter data and a simulation time parameter data for use in determining the DC power generation power data precisely.

Regarding the simulation test system, the daily irradiance parameter data and/or the simulation time parameter data is a value measured and related to the physical microgrid system operating within a period of time.

Regarding the simulation test system, the power generation module is a wind power generation module comprising a wind speed parameter input unit whereby a user enters a wind speed parameter data and a maximum power tracking unit for tracking maximum power generation power and maintaining stability of DC voltage, wherein the power generation data includes the wind speed parameter data entered and an adjustment parameter for use in adjusting the wind speed parameter data with the maximum power tracking unit to thereby determine the DC power generation power data.

Regarding the simulation test system, the power generation data further comprises a wind power generation equipment parameter data and a simulation time parameter data for use in determining the DC power generation power data precisely.

Regarding the simulation test system, the wind speed parameter data and/or the simulation time parameter data is a value measured and related to the physical microgrid system operating within a period of time.

Regarding the simulation test system, the bidirectional DC converter unit determines whether the energy storage module should be charged or discharge according to the level of power stored in the energy storage module.

Regarding the simulation test system, the AC end module comprises a load power consumption level parameter input unit whereby a user enters a load power consumption level parameter data, wherein the power consumption data comprises the load power consumption level parameter data whereby the data display module displays the degree of equilibrium according to the first power supply data, the second power supply data and the third power supply data.

Regarding the simulation test system, the power consumption data further comprises a load equipment parameter data and a simulation time parameter data for use in displaying the degree of equilibrium precisely.

Regarding the simulation test system, the AC utility grid unit is configured with a start mode and an islanding operation mode to generate the second power supply data automatically when the AC utility grid unit is operating in the start mode and set the second power supply data to zero when the AC utility grid unit is operating in the islanding operation mode.

In conclusion, the present invention provides an operation simulation test system of a cluster-based microgrid integrated with energy storages, characterized in that an operation simulation test of a physical microgrid system is conducted with a computer as well as a power generation data and a power consumption data which are imported. Hence, the user can verify the feasibility of applying various design concepts and ideas, such as controller parameter design and system energy management strategies, to a physical microgrid system, without installing or using any physical apparatuses.

### BRIEF DESCRIPTION

Objectives, features, and advantages of the present invention are hereunder illustrated with specific embodiments in conjunction with the accompanying drawings, in which:

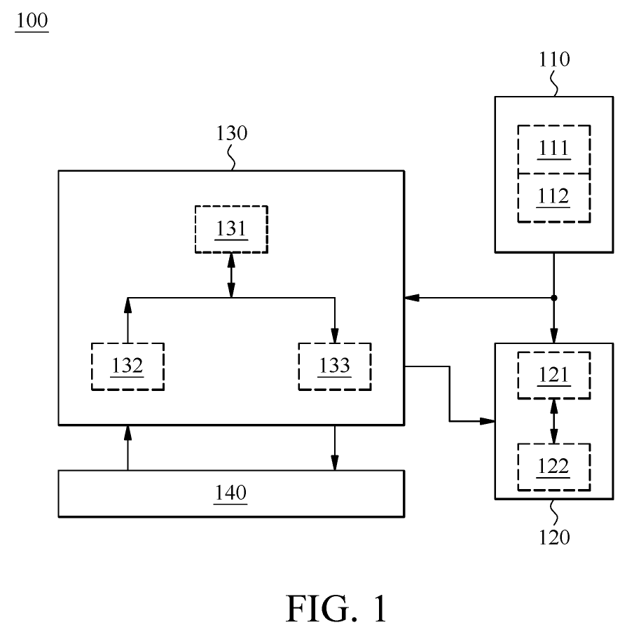

FIG. 1 is a schematic view of the framework of a physical microgrid system according to an embodiment of the present invention;

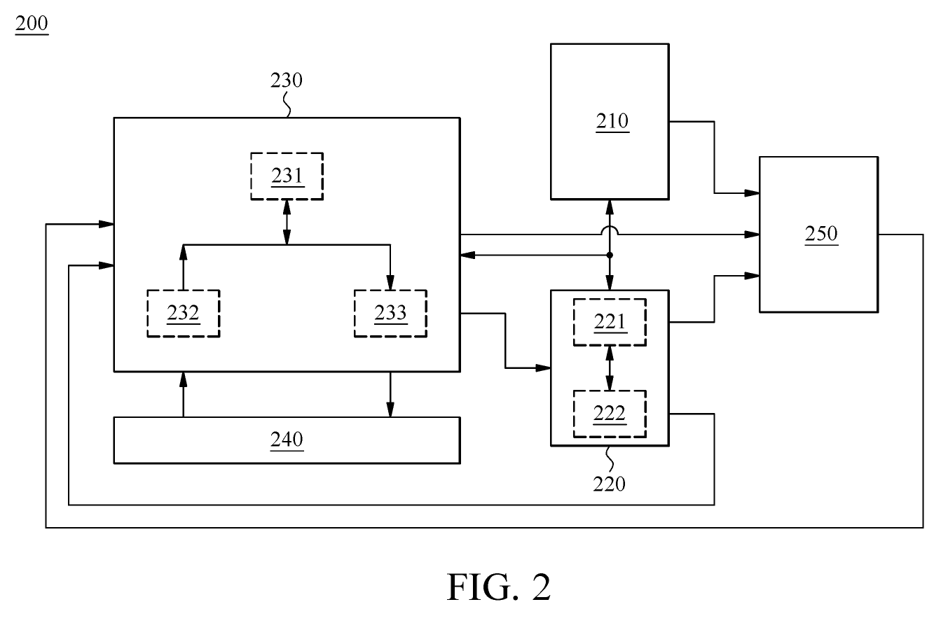

FIG. 2 is a schematic view of an simulation test system according to an embodiment of the present invention; and

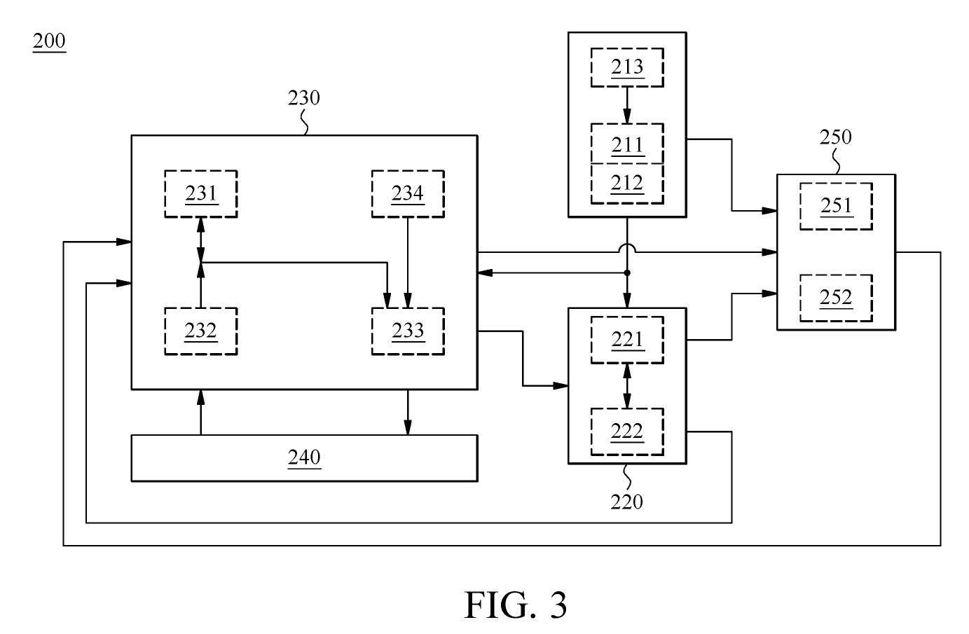

FIG. 3 is a schematic view of the simulation test system according to another embodiment of the present invention.

### DETAILED DESCRIPTION

Referring to FIG. 1, there is shown a schematic view of the framework of a physical microgrid system 100 according to an embodiment of the present invention.

The physical microgrid system 100 comprises a power generation module 110, an energy storage module 120, an AC end module 130 and a DC-AC inverter control module 140.

The power generation module 110 comprises any power generation unit which generates power from a renewable energy source. For example, the power generation module 110 is a solar power generation module composed of one or more solar power generation units, a wind power generation module composed of one or more wind power generation units, a fuel cell module composed of one or more fuel cell power generation units, or a renewable energy power generation module composed of solar, wind and fuel cell power generation units. Depending on the actual environmental parameters (such as a daily irradiance parameter and a wind parameter) and equipment parameters of the power generation units, the power generation module 110 in operation generates power accordingly. The power generation module 110 integrates the power derived from different renewable energy sources and then outputs the power to the energy storage module 120.

In this embodiment, the power generation module 110 is a solar power generation module which comprises a maximum power tracking circuit 111 and a solar photovoltaic module and array 112. The solar photovoltaic module and array 112 converts light energy into electrical energy. With the maximum power tracking circuit 111, the DC voltage of the solar power generation module is kept stable, and its maximum power output conditions are maintained.

The energy storage module 120 comprises various energy storage components 121. For example, the energy storage module 120 comprises plumbate batteries, lithium iron batteries and sodium sulfate batteries of various types or any specifications. The energy storage module 120 is provided to deal with the situation where the power generated from the power generation module 110 does not match the power required by the AC end module 130. To be specific, the microgrid system operates in a grid-connected mode or an islanding operation mode. Equilibrium between the power generated from the power generation module 110 operating in the islanding operation mode and the power required for the AC end module 130 seldom occurs. To maintain a stable power supply and avoid a waste of power, it is necessary for the energy storage module 120 to serve a regulatory purpose by storing or releasing power timely.

Since the power generation module 110 which generates power from a renewable energy source is flawed with unstable power generation, the energy storage module 120 connects with a utility grid to thereby increase, by utility power, the level of the power stored in the energy storage module as needed such that the utility power functions as standby power for supplementing renewable energy.

The energy storage module 120 comprises one or more bidirectional DC inverters 122 for controlling the energy storage component 121 to store/release power.

The AC end module 130 connects with the energy storage module 120 to receive DC power from the energy storage module 120. The AC end module 130 comprises a DC-AC inverter 131, an AC utility grid 132 and a load 133. The DC-AC inverter 131 converts DC power into AC power to meet the specifications of conventional AC electrical appliances. The AC utility grid 132 is, for example, an AC grid built by an electric utility to supplement a power supply as needed (for example, when the power demand of the load 133 exceeds the level of the power supplied by the power generation module 110 and the energy storage module 120). The load 133 is, for example, a power client which receives power supply and operates in capacity as household, office or factory.

The DC-AC inverter control module 140 is a circuit capable of performing pulse width modulation to drive the DC-AC inverter 131 to operate, thereby effectuating control and adjustment.

Referring to FIG. 2, there is shown a schematic view of an simulation test system 200 for performing an operation simulation test according to an embodiment of the present invention with reference to the physical microgrid system 100 of FIG. 1. As shown in the diagram, the operation simulation test is performed with a computer (such as a desktop computer or a notebook computer) as well as a power generation data and a power consumption data which are imported. Some of the simulation modules in the simulation test system 200 correspond in function to the modules of the physical microgrid system 100 as described below.

The simulation test system 200 comprises a power generation module 210, an energy storage module 220, an AC end module 230, a DC-AC inverter control module 240 and a data display module 250.

The power generation module 210 simulates the power generation module 110 of the physical microgrid system 100 according to the power generation data.

The power generation module 210 performs a simulation process according to various parameters measured while the simulation test system 200 is operating. Alternatively, the power generation module 210 performs a simulation process according to a presumptive virtual parameter configured by a user. For example, the power generation module 210 performs a simulation process to thereby determine the DC power generation power data generated from the power generation module 110 during an operation process, according to the actual equipment parameter data, actual daily irradiance parameter data, actual wind speed parameter data, or time parameter data of the power generation module 110. For example, the power generation module 210 performs a simulation process according to the equipment parameters, virtual daily irradiance parameters or virtual wind speed parameters, which are related to the power generation module 110 and configured by the user, so as to determine the DC power generation power data generated from the power generation module 110 during an operation process. Hence, the equipment parameters attributed to the power generation module 110 and configured by the user may exhibit behavioral characteristics differently from physical apparatuses.

The AC end module 230 simulates the load 133 of the physical microgrid system 100 according to the power consumption data. Similarly, the AC end module 230 performs a simulation process according to an actual parameter or even a user-defined parameter, such as a presumptive virtual parameter. For example, the AC end module 230 performs a simulation process according to the actual equipment parameters, actual power consumption level parameters and time parameters of the load 133 to thereby determine the power supply data of the load 133 in operation. For example, the AC end module 230 performs a simulation process according to the user-defined equipment parameters, virtual power consumption level parameters and simulation time parameters of the load 133 to thereby determine power supply data of the load 133 in operation.

The AC end module 230 comprises a DC-AC inverter unit 231, an AC utility grid unit 232 and a client load unit 233. The DC-AC inverter unit 231 converts DC power generation power data of the power generation module 210 fully or partially into first power supply data and then provides the first power supply data to the client load unit 233. Optionally or alternatively, the DC-AC inverter unit 231 converts DC power (i.e., third power supply data) provided by the energy storage module 220 into AC power and then supplies the AC power to the client load unit 233. The AC utility grid unit 232 supplies AC power (i.e., second power supply data) to the client load unit 233 as needed, so as to serve as a supplement.

The energy storage module 220 connects with the power generation module 210 and the AC end module 230 to simulate the energy storage module 120 of the physical microgrid system 100.

The charging input (i.e., the aforesaid power supplied by the AC utility grid unit 232) for the energy storage module 220 is provided according to the second power supply data or fully or partially provided according to the DC power generation power data. For example, in the course of supplying the DC power generation power data to the client load unit 233, power data left over from the first power supply data consumed by the client load unit 233 is entered for use in charging the energy storage module 220. When the first power supply data is insufficient to enable charging, the energy storage module 220 is charged by means of the second power supply data provided by AC utility grid unit 232, so as to determine the charging data of the energy storage module 220.

The DC-AC inverter control module 240 simulates the DC-AC inverter control module 140 of the physical microgrid system 100. The DC-AC inverter control module 240 connects with the DC-AC inverter unit 231 to provide a predetermined pulse width modulation parameter for use as the basis of the adjustment and control of AC power. The power generation module 210 connects with the DC-AC inverter unit 231 to provide the first power supply data through the adjustment based on the pulse width modulation parameter. The energy storage unit 220 connects with the DC-AC inverter unit 231 to provide the third power supply data through the adjustment based on the pulse width modulation parameter.

If the first power supply data provided as a result of the adjustment based on the pulse width modulation parameter is insufficient to be supplied to the client load unit 233, the third power supply data provided as a result of the adjustment based on the pulse width modulation parameter can be a supplement. Alternatively, the second power supply data can be a supplement.

The data display module 250 connects with the power generation module 210, energy storage module 220, AC end module 230 and DC-AC inverter control module 240 to enable the configuration of parameters, such as the power generation data, the power consumption data, the pulse width modulation parameter and the second power supply data, and enable the display of power generation data and/or power supply data, such as the DC power generation power data and the first through third power supply data.

The DC power generation power data and power supply data thus displayed comprises: (1) dynamic waveforms, transient waveforms and values of voltage, current and power; (2) quantified waveforms and values of normalized voltage, current and power; and (3) the other electrical waveforms and quantified indices, such as frequency, phase angle, and harmonic component.

For example, the user configures parameters, such as the power generation data, the power consumption data, the pulse width modulation parameter and the second power supply data, with the data display module 250. Then, computer software automatically substitutes the parameters into the power generation module 210, the energy storage module 220, the AC end module 230 and the DC-AC inverter control module 240 to thereby determine a power generation data and/or power supply data, such as the DC power generation power data and the first through third power supply data. Finally, the power generation data and/or power supply data is displayed on the data display module 250.

The user gains insight into statuses of the modules with reference to a control criterion of any parameter according to the data displayed on the data display module 250. Then, the user determines whether the statuses of the modules meet the expectations, for example, the degree of equilibrium between the power data required for the load 133 and a combination of the first through third power supply data, of the parameters designed by the user. If the power generation data and power supply data generated as a result of the simulation process does not meet the expectations, it indicates that the test fails and the user can design a parameter anew for entry.

Referring to FIG. 3, there is shown is a schematic view of the simulation test system 200 according to another embodiment of the present invention.

For example, the power generation module 210 is a solar power generation module and comprises a maximum power tracking unit 211 and a solar photovoltaic module and array unit 212. From the perspective of the simulation test system 200, the introduction of the operation of the maximum power tracking unit 211 amounts to a specific degree of the enhancement of the DC power generation power data. The extent of the enhancement of the DC power generation power data depends on the actual test parameters.

For example, the power generation module 210 further comprises an environmental parameter input unit 213 whereby the user enters various parameter data. For example, the environmental parameter input unit 213 is a daily irradiance parameter input unit and/or a wind speed parameter input unit. The daily irradiance parameter data and/or the wind speed parameter data is indicative of sunlight exposure and/or wind during the operation process, respectively.

For example, the AC end module 230 comprises a load power consumption level parameter input unit 234 whereby the user enters one or more load power consumption level parameter data. The load power consumption level parameter data indicates the power consumption requirement of the client load unit 233.

For example, the AC utility grid unit 232 is configured to operate in either a start mode or an islanding operation mode. When the AC utility grid unit 232 is set to the islanding operation mode, the AC end module 230 is not connected to any AC utility grid, and thus the second power supply data is set to zero. When the AC utility grid unit 232 is set to the start mode, the AC end module 230 is connected to an AC utility grid. Hence, the second power supply data is automatically generated according to the aforesaid equilibrium requirement.

For example, the data display module 250 comprises a parameter configuration unit 251 for configuring parameters and a data display unit 252 for displaying data to thereby perform the parameter configuration function and the data display function of the data display module 250, respectively.

In conclusion, the present invention provides an operation simulation test system of a cluster-based microgrid integrated with energy storages, characterized in that an operation simulation test of a physical microgrid system is conducted with a computer as well as a power generation data and a power consumption data which are imported. Hence, the user can verify the feasibility of applying various design concepts and ideas, such as controller parameter design and system energy management strategies, to a physical microgrid system, without installing or using any physical apparatuses.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A simulation test system of a microgrid, wherein an operation simulation test of a physical microgrid system is performed with a computer as well as a power generation data and a power consumption data which are imported, the computer comprising:
a power generation module for simulating a physical power generation module of a physical microgrid system according to the power generation data and sending a DC power generation power data;
a DC-AC inverter control module having a predetermined pulse width modulation parameter to provide a basis of adjustment and control of AC power;
an AC end module comprising a DC-AC inverter unit and an AC utility grid unit, with the AC end module adapted to simulate a load of a physical microgrid system according to the power consumption data, wherein the DC-AC inverter unit connects with the DC-AC inverter control module and the power generation module to convert a portion attributed to the DC power generation power data and supplied to the load into a first power supply data according to the pulse width modulation parameter, wherein the AC utility grid unit provides a second power supply data selectively to the load;
an energy storage module connected to the power generation module and the AC end module to simulate a physical energy storage module of a physical microgrid system, wherein the energy storage module comprises an energy storage unit and a bidirectional DC converter unit connected to the AC utility grid unit of the AC end module through the DC-AC inverter unit, wherein the energy storage unit connects with the DC-AC inverter unit to provide a third power supply data selectively according to the pulse width modulation parameter, wherein the bidirectional DC converter unit receives one of the second power supply data and the DC power generation power data to thereby provide a charging data to the energy storage module, wherein the DC power generation power data received by the energy storage module is a power data left over from the first power supply data consumed by the load; and
a data display module connected to the power generation module, the DC-AC inverter control module, the AC end module and the energy storage module to enable parameter configuration of the power generation data, the power consumption data, the pulse width modulation parameter and the second power supply data, enable display of the DC power generation power data, the first power supply data and the third power supply data, and display a degree of equilibrium of a combination of a power data required for the load and the first through third power supply data.

2. The simulation test system of claim 1, wherein the power generation module is a solar power generation module comprising a daily irradiance parameter input unit which a user enters a daily irradiance parameter data and a maximum power tracking unit for tracking maximum power generation power and maintaining stability of DC voltage, wherein the power generation data includes the daily irradiance parameter data entered and an adjustment parameter for use in adjusting the daily irradiance parameter data with the maximum power tracking unit to thereby determine the DC power generation power data.

3. The simulation test system of claim 2, wherein the power generation data further comprises a solar power generation equipment parameter data and a simulation time parameter data for use in determining the DC power generation power data precisely.

4. The simulation test system of claim 3, wherein at least one of the daily irradiance parameter data and the simulation time parameter data is a value measured and related to the physical microgrid system operating within a period of time.

5. The simulation test system of claim 1, wherein the power generation module is a wind power generation module comprising a wind speed parameter input unit whereby a user enters a wind speed parameter data and a maximum power tracking unit for tracking maximum power generation power and maintaining stability of DC voltage, wherein the power generation data includes the wind speed parameter data entered and an adjustment parameter for use in adjusting the wind speed parameter data with the maximum power tracking unit to thereby determine the DC power generation power data.

6. The simulation test system of claim 5, wherein the power generation data further comprises a wind power generation equipment parameter data and a simulation time parameter data for use in determining the DC power generation power data precisely.

7. The simulation test system of claim 6, wherein at least one of the wind speed parameter data and the simulation time parameter data is a value measured and related to the physical microgrid system operating within a period of time.

8. The simulation test system of claim 1, wherein the bidirectional DC converter unit determines whether the energy storage module should be charged or discharge according to the level of power stored in the energy storage module.

9. The simulation test system of claim 1, wherein the AC end module comprises a load power consumption level parameter input unit whereby a user enters a load power consumption level parameter data, wherein the power consumption data comprises the load power consumption level parameter data whereby the data display module displays the degree of equilibrium according to the first power supply data, the second power supply data and the third power supply data.

10. The simulation test system of claim 9, wherein the power consumption data further comprises a load equipment parameter data and a simulation time parameter data for use in displaying the degree of equilibrium precisely.

11. The simulation test system of claim 10, wherein at least one of the load power consumption level parameter data and the simulation time parameter data is a value measured and related to the physical microgrid system operating within a period of time.

12. The simulation test system of claim 1, wherein the AC utility grid unit is configured with a start mode and an islanding operation mode to generate the second power supply data automatically when the AC utility grid unit is operating in the start mode and set the second power supply data to zero when the AC utility grid unit is operating in the islanding operation mode.
